(19) United States
(12) Patent Application Publication
(10) Pub. No.: US 2008/0308799 A1
(43) Pub. Date: Dec. 18, 2008

(54) WIRING STRUCTURE AND MANUFACTURING METHOD THEREFOR

(75) Inventor: Koji Tamura, Hiroshima (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 12/135,448

(22) Filed: Jun. 9, 2008

(30) Foreign Application Priority Data
Jun. 12, 2007 (JP) 2007-155524

(51) Int. Cl. H01L 23/58; H01L 21/66

(52) U.S. Cl. 257/48; 438/16; 257/E21.521

(57) ABSTRACT

A wiring structure including a wiring pattern formed in an insulation film on a substrate, a pattern for measurement which is formed in the insulation film on the substrate in a region different from a region where the wiring pattern is formed and is irradiated with measuring light, and a light transmission inhibiting film formed directly below the pattern for measurement, wherein the pattern for measurement is the same pattern as the wiring pattern, and the light transmission inhibiting film is made of a material having light transmissivity that is smaller than light transmissivity of a material of the insulation film forming the pattern for measurement.

### CROSS-REFERENCE TO RELATED APPLICATION

This application is related to Japanese patent application No. 2007-155524 filed on Jun. 12, 2007 whose priority is claimed.

### BACKGROUND OF THE INVENTION

1. Field of the Invention

The present invention relates to a wiring structure and a method of producing the same, and more specifically, to a wiring structure and a method of producing the same capable of controlling a shape and a dimension and improving measuring accuracy of a wiring pattern.

2. Description of the Related Art

In production of a semiconductor device, for example, dimensions of a gate electrode pattern, a wiring pattern and the like of a transistor greatly influence on electric characteristics. In order to improve the quality and performance of the transistor or the wiring, it is very important to control a shape of a pattern to be formed in a pattern forming step at high speed, with high accuracy in a non-destructive manner.

By reducing a variation in a shape of a transistor or a wiring pattern through a sophisticated process control such as APC (Advanced Process Control) based on a measurement result of a pattern shape including a line width, a film thickness and a pitch of the pattern, it is possible to greatly improve the quality and performance thereof.

For example, as a method of measuring a wiring width, a film thickness, a wiring pitch and the like of a wiring pattern, an optical shape measuring methods such as an ellipsometry that conducts measurement in a non-destructive manner using visible light or UV light, a length-measuring SEM method that measures a pattern dimension in a non-destructive manner using electron beam, a cross-section SEM method that destructively inspects a cross section shape of a pattern using electron beam and the like can be exemplified.

In production of a semiconductor device, from the view point of improving productivity, it is demanded to measure a pattern shape of a wiring, an element and the like at high speed in a non-destructive manner. Recently, a scatterometry method that measures a wiring width, a film thickness, a pattern interval, a cross section shape included in a pattern shape using visible light and UV light has been developed to respond to such a demand.

The scatterometry method enables a three-dimensional shape of a pattern to be measured by fitting a theoretical waveform calculated from various optical characteristic values such as a pattern shape, a refractive index and a dielectric constant of the pattern measured by using linear polarization, with an actually measured wavelength.

As for a shape control method of a pattern in a production process of a semiconductor device, various proposals have been made, and for example, Japanese Patent Application Laid-open Publication No. 2006-100619 describes a method of controlling a pattern shape during a process by forming a pattern for measurement which is called a TEG (test element group) in a device forming region or a scribe region in a semiconductor wafer, and measuring a dimension by using an optical shape measuring method such as the scatterometry method, various SEM methods as described above on the TEG.

In such pattern shape control during a process using a pattern for measurement, the shape control of an upper layer wiring pattern in a semiconductor device having an upper layer wiring pattern is generally conducted during a production process, as shown in FIGS. 5(A1) to (C2) and FIGS. 6(A1) to (B2). FIGS. 5(A1) to (C2) and FIGS. 6(A1) to (B2) are process diagrams showing a part of a production process of a conventional wiring structure, in which the diagrams (A1) to (C1) on a left side in FIG. 5 and the diagrams (A1) to (B1) on a left side of FIG. 6 show production steps of a device forming region on a semiconductor substrate, and the diagrams (A2) to (C2) on a right side in FIG. 5 and (A2) to (B2) on a right side in FIG. 6 show production steps of a scribe region on a semiconductor substrate.

FIGS. 5(A1) and (A2) show a condition in which a base device structure 201 and a base scribe structure 202 are formed on a semiconductor substrate 1 in a form of a wafer having an element separation film 2, and on the base device structure 201 and the base scribe structure 202, a lower layer wiring pattern 208 and a lower layer wiring pattern for measurement 209 are formed.

The base device structure 201 includes a FET 13a having a gate oxidation film, a gate electrode 3, a side wall spacer 4, and a source/drain region 5, which are formed on the semiconductor substrate 1, an interlayer insulation film 6 covering the FET 13a, and a contact plug 7 that penetrates through the interlayer insulation film 6 and electrically connects the source/drain region 5 and the lower layer wiring pattern 208.

The base scribe structure 202 has a FET for measurement 13b having the same design dimension with the FET 13a of the base device structure 201 and having a gate oxidation film, the gate electrode 3, the side wall spacer 4, and the source/drain region 5, which are formed on the semiconductor substrate 1, the interlayer insulation film 6 covering the FET for measurement 13b, and the contact plug 7 that penetrates through the interlayer insulation film 6 and connects the source/drain region 5 of the FET for measurement 13b and the lower layer wiring pattern for measurement 209. Further, the gate electrode 3 and the side wall spacer 4 in the FET for measurement 13b are provided for measuring shapes of the gate electrode 3, the side wall spacer 4 and the like in the base device structure 201 using the aforementioned optical shape measuring method, and are formed according to the same design layout as that of the base device structure 201.

A lower layer wiring pattern 208 and a lower layer wiring pattern for measurement 209 are formed so that they are embedded in a first insulation film 203 and a second insulation film 204 which are formed on the base device structure 201 and the base scribe structure 202. Further, the lower layer wiring pattern for measurement 209 in the scribe region is provided for measuring a shape of the lower layer wiring pattern 208 in the device forming region by the aforementioned optical shape measuring method, and is formed according to the same design layout as that of the lower layer wiring pattern 208.

And in forming an upper layer wiring pattern 218 on the lower layer wiring pattern 208 in the device forming region formed in this manner (see FIG. 6(B1)), first, as shown in FIGS. 5(A1) and (A2), on the lower layer wiring pattern 208 and the second insulation film 204, a third insulation film 210 and a fourth insulation film 211 are sequentially formed. Thereafter, on the fourth insulation film 211, a resist pattern 212 is formed. At this time, a pattern having a mask opening part only in the device forming region is formed.

Then, dry etching using the resist pattern 212 as a mask is conducted, to form a via-hole 213 in the fourth insulation film 211 in the device forming region as shown in FIG. 5(B1). At this time, the third insulation film 210 functions as an etching stopper layer. On the other hand, as shown in FIG. 5(B2), no via-hole is formed in the fourth insulation film 211 in the scribe region. Then, the resist pattern 212 is removed.

Subsequently, as shown in FIGS. 5(C1) and (C2), an embedding film 214 is deposited on the fourth insulation film 211 in such a film thickness that completely embeds inside the via-hole 213, and a new resist pattern 215 is formed on the embedding film 214. At this time, as shown in FIG. 5(C1), the device forming region in the resist pattern 215 is formed with a mask opening part according to a design layout of a pattern shape including a wiring width, a film thickness and a wiring pitch (pattern interval) of the upper layer wiring pattern 218 (see FIG. 6(B1)), and in a similar manner, the scribe region in the resist pattern 215 is formed with a mask opening part according to the design layout of an upper layer wiring pattern 218. As a result, the part of the mask opening part of the resist pattern 215 in the device forming region is situated at the position of the via-hole 213.

Next, the embedding film 214 and the fourth insulation film 211 are dry-etched using the resist pattern 215 as a mask. This dry etching is controlled, as shown in FIGS. 5(C1) and (C2) and FIGS. 6(A1) and (A2), so that in the device forming region and in the scribe region, a groove pattern for upper layer wiring 216 and a groove pattern for measurement 217 having the same film thickness and depth as the upper layer wiring pattern 218 to be formed are formed in the fourth insulation film 211. Further, in this dry etching, in the device forming region, the embedding film 214 in the via-hole functions as a protective film for the third insulation film 210, and the embedding film 214 remains in the via-hole.

Thereafter, plasma ashing is conducted using ashing gas such as oxygen, to remove the resist pattern 215 and the embedding film 214, and then dry etching is conducted to remove the third insulation film 210, whereby as shown in FIGS. 6 (A1) and (A2), the via-hole 213 that reaches to the lower layer wiring pattern 208 is formed in the device forming region and a part of the groove pattern for upper layer wiring 216 communicates with the via-hole 213.

Next, a conductive metal film is deposited on the fourth insulation film 211 in such a film thickness that is completely embedded in the via-hole 213 and the groove pattern for upper layer wiring 216, and the metal film on the surface is removed by CMP (chemical mechanical polishing) to make the fourth insulation film 211 be exposed. As a result, in the device forming region, a via pattern 220 and the upper layer wiring pattern 218 are formed as shown in FIG. 6(B1), while at the same time, as shown in FIG. 6(B2), an upper layer wiring pattern for measurement 219 is formed in the scribe region.

In such a production process of a conventional semiconductor device, the shape of the upper layer wiring pattern 218 is controlled in the step previous to the deposition of the metal film, by measuring the shape of the groove pattern for measurement 217 using the optical shape measuring method such as a scatterometry method, various SEM methods and the like. At this time, for example, shape measurement of the groove pattern for measurement 217 by the scatterometry method is conducted in the following manner.

(1) Make linear polarization enter the groove pattern for measurement 217.

(2) Measure diffraction rays in horizontal and vertical directions of the pattern.

(3) Conduct spectrum analysis by comparing the diffraction rays in the horizontal and vertical directions of the pattern, with a theoretical waveform calculated from a film structure of the groove pattern for measurement 217. At this time, a film thickness, an upper side dimension, a lower side dimension, and a side wall angle of the layer in which the groove pattern for measurement 217 is formed are essential parameters, and these essential parameters are adjusted to change the theoretical waveform, and fitting with an actually measured waveform is conducted, and optimum solutions of the necessary parameters are determined.

(4) Output values of essential parameters (film thickness, upper side dimension, lower side dimension, and side wall angle) where optimum fitting is achieved between an actually measured waveform and a theoretical waveform, and fitting accuracy as a measurement result.

(5) As for the fitting accuracy, determine whether the measurement is good or not with respect to predetermined criteria.

However, in the pattern shape control in such a production process of a conventional semiconductor device, when the shape of the groove pattern for measurement 217 in the scribe region is measured by using the aforementioned optical shape measuring method, the measurement is greatly influenced by an under-layer structure situated below the groove pattern for measurement 217, such as a laminate film structure having high light transmittance including the third insulation film 210, the second insulation film 204, the first insulation film 203 and the like, and the lower layer wiring pattern for measurement 209 and the base scribe structure 202 formed in the laminate film structure. As a result, the number of parameters in measurement increases, leading deterioration in measurement accuracy, so that it is impossible to measure shape of the groove pattern for measurement 217 with high accuracy.

In other words, when the shape of the conventional groove pattern for measurement 217 is measured by the aforementioned optical shape measuring method, the necessity arises that a large number of unwanted parameters should be taken into account, including a film thickness of the third insulation film 210, a film thickness, an upper side dimension, a lower side dimension and a side wall angle of the second insulation film 204, a film thickness, an upper side dimension, a lower side dimension and a side wall angle of the first insulation film 203, a film thickness, an upper side dimension, a lower side dimension and a side wall angle of the lower layer wiring for measurement 209, a film thickness, an upper side dimension, a lower side dimension and a side wall angle of the interlayer insulation film 6 situated below the fourth insulation film 211, besides the essential parameters including a thickness of the fourth insulation film 211 and a depth, an upper side dimension, a lower side dimension, and a side wall angle of the groove pattern for measurement 217. As described above, when the number of parameters that should be taken into account besides the essential parameters increases, a local solution that allows a certain degree of fitting tends to result due to combinations of parameters that is different from actual dimensions, and it becomes difficult to obtain an optimum solution. This deteriorates measurement accuracy.

### SUMMARY OF THE INVENTION

The present invention was made in view of such a problem, and it is an object of the present invention to provide a wiring structure and a method of producing the same capable of controlling a pattern shape with high accuracy by suppressing influence of an under-layer structure.

Thus, according to the present invention, there is provided a wiring structure including a wiring pattern formed in an insulation film on a substrate, a pattern for measurement which is formed in the insulation film on the substrate, in a region different from a region where the wiring pattern is formed and is irradiated with measuring light, and a light transmission inhibiting film formed directly below the pattern for measurement, wherein the pattern for measurement is the same pattern as the wiring pattern, and the light transmission inhibiting film is made of a material having light transmissivity that is smaller than light transmissivity of a material of the insulation film forming the pattern for measurement.

Also, according to another aspect of the present invention, there is provided a method of producing the wiring structure including the steps of: (a) forming the light transmission inhibiting film on the substrate, (b) forming an insulation film directly above the light transmission inhibiting film and forming the pattern for measurement in the insulation film, and (c) forming an insulation film on the substrate in a region which is different from that of the light transmission inhibiting film and forming the wiring pattern in the insulation film, wherein the step (b) and the step (c) are conducted concurrently.

According to the present invention, when shape measurement of the pattern for measurement is conducted by an optical shape measuring method, the measuring light for irradiating the pattern for measurement is difficult to transmit the layers under the layer having the pattern for measurement, owing to the light transmission inhibiting film. As a result, even when the wiring structure has an under-layer structure including a wiring pattern, a base device or the like under the pattern for measurement, it is possible to conduct appropriate optical measurement while suppressing the influence of the under-layer structure other than the pattern for measurement to be measured, and to conduct the shape measurement of the pattern for measurement with high accuracy. Therefore, it is possible to reduce the variation by a sophisticated process control such as APC or the like, based on the highly accurate shape measurement result of the pattern for measurement, and to greatly improve the quality and performance of the device or wiring such as a transistor, a memory, a resistance or a capacitor.

Further, since the pattern for measurement is originally not intended for operation, the device forming region can be formed in a necessary minimum area by forming the pattern for measurement in a region different from that of the device forming region. Further, if necessary, the region of the pattern for measurement may be removed, and a chip only including the device forming region may be produced without increasing the chip area.

### BRIEF DESCRIPTION OF THE DRAWINGS

FIGS. 1(A1) to (C2) are process diagrams for explaining a first embodiment of a production method of a wiring structure according to the present invention;

FIGS. 2(A1) to (C2) are process diagrams subsequent to FIGS. 1(C1) and (C2);

FIG. 3(A1) to (B2) are process diagrams subsequent to FIGS. 2(C1) and (C2);

FIG. 4 is a arrangement view showing a device forming region and a region of an upper layer wiring pattern for measurement in the first embodiment of the present invention;

FIGS. 5(A1) to (C2) are process diagrams showing a production process of a conventional wiring structure; and

FIGS. 6 (A1) to (B2) are process diagrams subsequent to FIGS. 5(C1) and (C2).

### DETAILED DESCRIPTION OF THE INVENTION

A wiring structure of the present invention includes a wiring pattern formed in an insulation film on a substrate, a pattern for measurement which is formed in the insulation film on the substrate in a region different from a region where the wiring pattern is formed, and is irradiated with measuring light, and a light transmission inhibiting film formed directly below the pattern for measurement, wherein the pattern for measurement is the same pattern as the wiring pattern, and the light transmission inhibiting film is made of a material having light transmissivity that is smaller than light transmissivity of a material of the insulation film forming the pattern for measurement.

The wiring structure may be produced by a method of producing the wiring structure including the steps of: (a) forming the light transmission inhibiting film on the substrate, (b) forming an insulation film directly above the light transmission inhibiting film and forming the pattern for measurement in the insulation film, and (c) forming an insulation film on the substrate in a region which is different from the region where the light transmission inhibiting film is formed and forming the wiring pattern in the insulation film, wherein the step (b) and the step (c) are conducted concurrently.

In other words, the present invention is a wiring structure and a method of producing the same, capable of controlling a shape by checking whether the wiring pattern is formed in conformance with a design layout when shape measurement of the pattern for measurement is conducted according to an optical shape measuring method, and of conducting shape measurement at high accuracy by preventing the measuring light irradiating the pattern for measurement from transmitting to layers under the light transmission inhibiting film by the light transmission inhibiting film formed directly below the pattern for measurement, and thus reducing the influence of under-layer structure occurring during the shape measurement. In other words, since the measuring light is analyzed after being reflected mainly by the pattern for measurement and the light transmission inhibiting film, it is possible to reduce the number of parameters to be adjusted in the shape measurement to minimum necessary, and hence it is possible to measure a pattern shape with high accuracy.

The wiring structure and the method of producing the same of the present invention may be applied to electronic devices such as system LSI, CMOS image sensor, flush memory and the like.

Here, in the present invention, definition of the term pattern for measurement includes actual patterns such as wiring, electrode and the like which are objects to be measured, groove patterns for forming such actual patterns, and resist patterns for forming such groove patterns.

In the present specification, the term “optical shape measuring method” means a scatterometry method, a length-measuring SEM method, a cross-section SEM method, an ellipsometry and the like optical measuring methods that are commonly used in the art. Further, the term “a shape of a pattern” means, when the pattern is a wiring pattern or an electrode pattern, a shape including parameters such as a width of the wiring or the electrode, a film thickness, a pitch of the wiring or the electrode, and means, when the pattern is a groove pattern or a resist pattern, for example, a shape including parameters of a groove width, a groove depth, a side-wall angle, a groove pitch and the like.

The wiring structure of the present invention may further include a lower layer pattern structure including at least one of a wiring and an element direct by below the light transmission inhibiting film in addition to the aforementioned structure. In this case, it is possible to prevent the measuring light irradiating the pattern for measurement by using an optical shape measuring method from reaching the lower layer pattern structure by means of the light transmission inhibiting film. Therefore, a wiring structure having a device pattern of, for example, a transistor, a memory, a resistance, a capacitor or the like, or a lower layer wiring pattern, or a pattern for measurement (pattern for test) for measuring the shape thereof, as the lower layer pattern structure may be configured.

Further, in the present invention, as the substrate, for example, a semiconductor substrate, a SOI substrate, glass plate, a plastic sheet substrate and the like may be used without any particular limitation.

Further, the substrate may have a plurality of device forming regions and a scribe region partitioning the plurality of device forming regions, and the wiring pattern may be formed in the device forming region and the pattern for measurement may be formed in the scribe region. According to such a configuration, for example, after forming wiring structures on a plurality of the device forming regions on the semiconductor wafer, it is possible to form a plurality of chips without making them be unnecessarily bulky by cutting the scribe regions. In this case, another pattern for measurement may be formed as the aforementioned lower layer pattern structure directly below the light transmission inhibiting film. For example, when a certain room is allowed for the area of the device forming region, the pattern for measurement may be provided in the device forming region.

Further, the shape of the device forming region is not particularly limited, however, when it is in an even quadrangle shape, the pattern for measurement may be arranged along each side in four circumferential sides of the device forming region. In this case, one or two or more pattern for measurement may be arranged along each side of the device forming region. Further, as described above, the pattern for measurement may be in the device forming region or in the scribe region.

In this manner, it is possible to measure a shape of an arbitrary plurality of regions in the wiring pattern within the device forming region while they are assigned to a plurality of patterns for measurement. That is, shape control can be achieved in a plurality of regions with different pattern shapes in the wiring pattern. Further, by uniforming positions of the plurality of patterns for measurement arranged in respective sides of the device forming region in all of the device forming regions, whether difference in the pattern shape arises between a center part and a peripheral part on the substrate can be observed.

The wiring structure of the present invention having such device forming regions and a scribe region may be configured in the following manner.

The device forming region has a base device structure formed on a surface of a substrate, a first insulation film formed on the base device structure, a second insulation film formed on the first insulation film, a lower layer wiring pattern formed inside the first insulation film and the second insulation film, a third insulation film formed on the lower layer wiring pattern, a fourth insulation film formed on the third insulation film, and the wiring pattern formed inside the third insulation film and the fourth insulation film, and the scribe region has the lower layer pattern structure formed on the surface of the substrate, for measuring dimension of the base device structure, the first insulation film and the second insulation film formed on the lower layer pattern structure, the light transmission inhibiting film formed inside the first insulation film and the second insulation film, the third insulation film and the fourth insulation film formed on the light transmission inhibiting film, and the pattern for measurement formed inside the third insulation film and the fourth insulation film.

Such a wiring structure is applicable, for example, to a semiconductor device having a field effect transistor.

In the present invention, the measuring light may be obtained by an optical shape measuring apparatuses capable of executing various optical measuring methods as described above, and a wavelength thereof is appropriately from 200 nm to 800 nm, preferably from 100 nm to 1000 nm, and more preferably from 200 nm to 800 nm. Setting the wavelength of the measuring light at 200 nm to 800 nm advantageously realizes measurement with high sensitivity and low damage. In an extreme ultraviolet region of less than 200 nm, there is a fear that film quality of the material to be measured changes by the energy of the measuring light, while on the other hand, in an infrared region of more than 800 nm, it is expected that detection sensitivity of substance decreases as the wavelength is long, compared to the ultraviolet and visible regions of 200 nm to 800 nm.

In the present invention, a material of the light transmission inhibiting film is not particularly limited insofar as it has light transmissivity that is smaller than light transmissivity of the material forming the pattern for measurement, and may be conductive or insulating. Concrete examples of the material of the light transmission inhibiting film include inorganic materials such as Cu, Al, W, WN, Ta, TaN, Ti, TiN, SiN or SiON, and examples of the material of the insulation film forming the pattern for measurement include inorganic insulating materials such as silicon oxide, SiOF, SiOC, SiC, SiCN, porous silica or the like.

Light transmissivity with respect to the measuring light having a wavelength of 200 nm to 800 nm, of the insulation film forming the light transmission inhibiting film and the pattern for measurement varies depending on the material, film thickness and the like, and light transmissivity of the light transmission inhibiting film is preferably 0 to 0.95 time, more preferably 0 to 0.7 time, and particularly preferably 0 to 0.5 time the light transmissivity of the insulation film forming the pattern for measurement.

In the present invention, the light transmission inhibiting film has a two-dimensional size of equal to or larger than the beam diameter of the measuring light, and the pattern for measurement has a two-dimensional size of equal to or larger than the beam diameter of the measuring light, and may have a wiring width and a wiring pitch of from one-tenth to 10 times of a wavelength of the measuring light. In this manner, it is possible to measure the shape of the pattern for measurement with high accuracy without influenced by an under-layer structure of the light transmission inhibiting film, so that it is possible to set a lower limit value and an upper limit value of a design dimension of the pattern for measurement.

Further, the two-dimensional size of the pattern for measurement may be 10 μm square or more and 100 μm or less. In other words, as for a two-dimensional size of the pattern for measurement, a lower limit value may be set with respect to the beam diameter of measuring light, and an upper limit value may be set with respect to a design rule of the wiring pattern.

Further, the pattern for measurement may be a repeated pattern having a single wiring width and a single wiring pitch. This allows measurement of the shape by a scatterometry using interference of light.

In the following, embodiments of a wiring structure and a production method thereof of the present invention will be explained with reference to attached drawings.

### First Embodiment

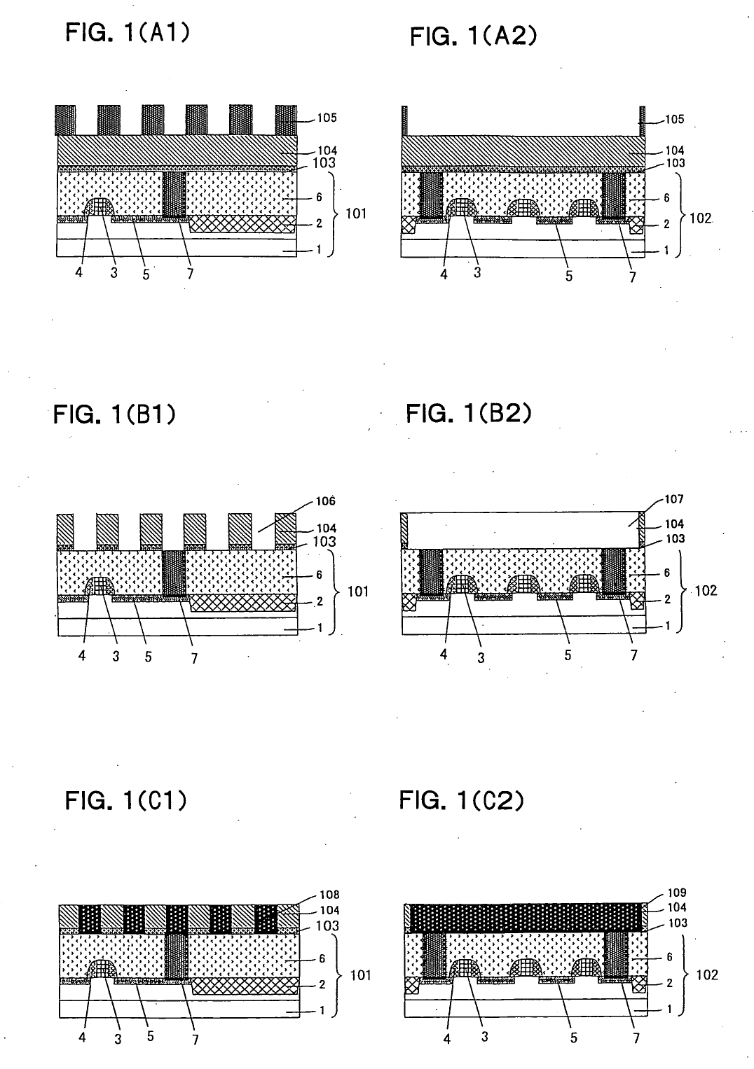

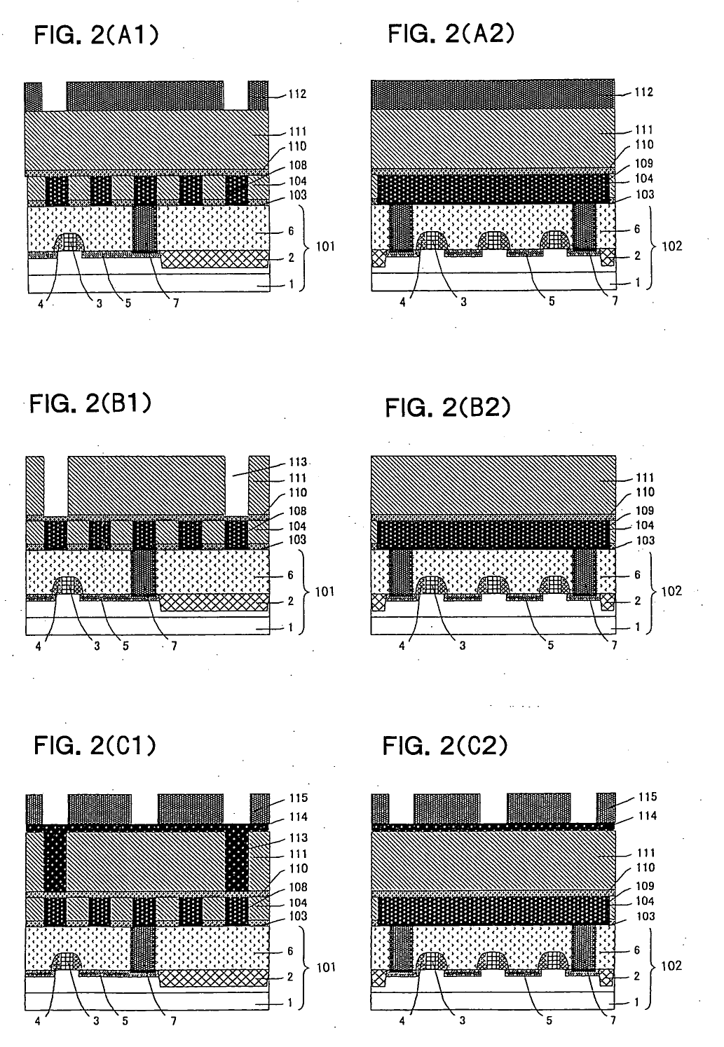

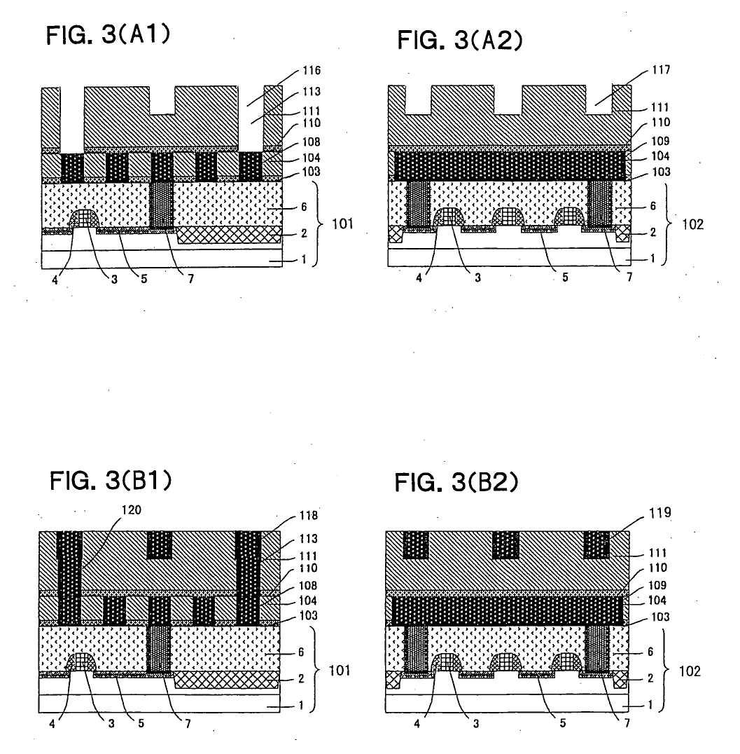

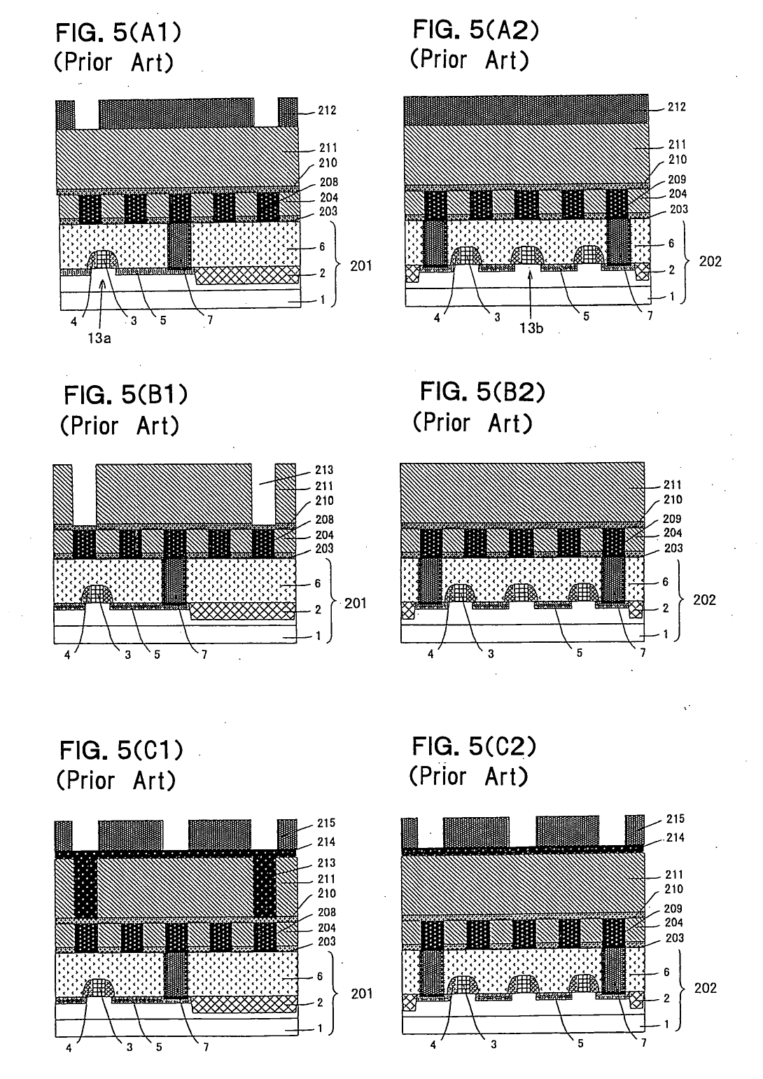

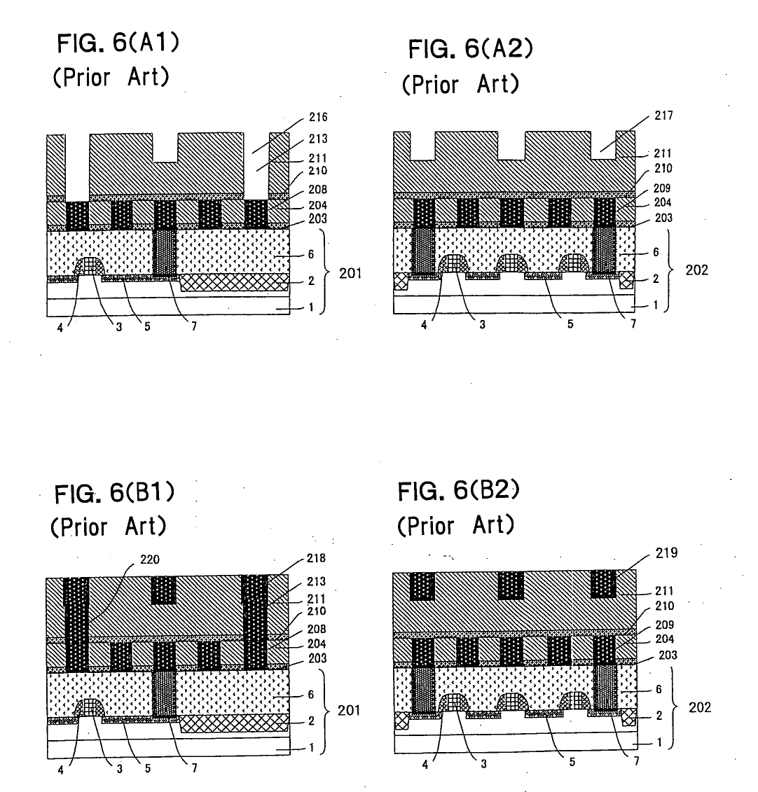

FIGS. 1(A1) to (C2), 2(A1) to (C2), and 3(A1) to (B2) are process diagrams explaining the first embodiment of a production method of a wiring structure according to the present invention. The diagrams (A1) to (C1) on the left side in FIG. 1, the diagrams (A1) to (C1) on the left side in FIG. 2 and the diagrams (A1) to (B1) on the left side of FIG. 3 show production steps of a device forming region on a semiconductor substrate, and the diagrams (A2) to (C2) on the right side in FIG. 1, the diagrams (A2) to (C2) on the right side in FIG. 2 and the diagrams (A2) to (B2) on the right side in FIG. 3 show production steps of a scribe region on a semiconductor substrate. In FIGS. 1(A1) to (C2), 2(A1) to (C2), and 3(A1) to (B2), the same element as that described in FIGS. 5(A1) to (C2) and FIGS. 6(A1) to (B2) is denoted by the same reference numeral.

In the first embodiment, as shown in FIGS. 3(B1) and (B2), a wiring structure applied to a semiconductor device having a FET (field effect transistor) is exemplified.

In production of this wiring structure, first as shown in FIGS. 1(A1) and (A2), an element separation film 2 is formed on a semiconductor substrate 1, and a gate oxidation film, a gate electrode 3, a side wall spacer 4, and a source/drain region 5 are formed in a device forming region and in a scribe region, to produce a FET. The FET formed in the scribe region is a testing device pattern for measuring whether the FET to be formed in the device forming region is formed in a desired shape, dimension and pattern interval, by way of the scatterometry method, various SEM methods and so on.

Next, an interlayer insulation film 6 is formed on the semiconductor substrate 1 having the FET, and a contact hole communicating with the source/drain region 5 is formed in the interlayer insulation film 6, and a conductive material is embedded in the contact hole, to form a contact plug 7. In this manner, a base device structure 101 is formed in the device forming region, and a base scribe structure 102 is formed in the scribe region. The base device structure 101 and the base scribe structure 102 correspond to the lower layer pattern structure as described above.

Thereafter, the production method of the wiring structure according to the present invention includes the steps of: (a) forming a light transmission inhibiting film on the semiconductor substrate 1; (b) forming an insulation film directly above the light transmission inhibiting film and forming the pattern for measurement in the insulation film; and (c) forming an insulation film on the semiconductor substrate 1 in a region which is different from that of the light transmission inhibiting film, and forming the wiring pattern in the insulation film, and the step (b) and the step (c) are conducted concurrently.

The wiring pattern formed in the step (b) means an upper layer wiring pattern in the present first embodiment, and a lower layer wiring pattern which is electrically connected with the upper layer wiring pattern is formed in the step (a).

First, in the step (a), on the interlayer insulation film 6 and the contact plug 7, a first insulation film 103 having a film thickness of 10 to 100 nm and a second insulation film 104 having a film thickness of 100 to 300 nm are sequentially formed. Here, the first insulation film 103 serves as an etching stopper layer when the later-described lower layer wiring pattern is formed in the second insulation film 104, and may be implemented by an inorganic insulation film made of, for example, SiC, SiCN and the like. The second insulation film 104 may be implemented by an inorganic insulation film made of, for example, silicon oxide, SiOF, SiOC, porous silicon and the like.

Thereafter, on the second insulation film 104, a first resist pattern 105 having a film thickness of about 100 nm to 1000 nm is formed for forming a lower layer wiring pattern in the first insulation film 103 and the second insulation film 104. In the first resist pattern 105, the device forming region has the same pattern as the lower layer wiring pattern to be formed (see FIG. 1(A1)), while the scribe region has an opening of a large area (see FIG. 1(A2).

The first resist pattern 105 may be formed by a known method, and for example, may be formed by applying a photoresist composition, exposing it to light with an optimum light exposure amount and focus using a KrF excimer laser scanner, and conducting development. As the photoresist composition, for example, a chemical amplification positive-type photoresist composition containing a commonly used base resin, an acid generator and the like may be used.

Next, as shown in FIGS. 1(A1) and (A2) and in FIGS. 1(B1) and (B2), the second insulation film 104 is dry-etched by using etching gas such as CₓF_{y}, CₓH_{y}F_{z}, O₂, CO, Ar or the like until the first insulation film 103 is exposed by using the first resist pattern 105 as a mask, and then sequentially the first insulation film 103 is dry-etched by using etching gas such as CₓF_{y}, CₓH_{y}F_{z}, O₂, CO, Ar or the like, to form a groove pattern for lower layer wiring 106 in the second insulation film 104 and in the first insulation film 103 in the device forming region, while the second insulation film 104 and the first insulation film 103 in the scribe region are removed to form a lower layer large area groove pattern 107.

Thereafter, plasma ashing is conducted using ashing gas containing oxygen gas, to remove the first resist pattern 105.

Then, on the entire surface of the second insulation film 104 including an inside of the groove pattern for lower layer wiring 106 and the lower layer large area groove pattern 107, a conductive metal for embedding wiring, for example, copper (Cu) is deposited with a thickness of 500 nm to 1000 nm by a sputtering method and a plating method, and then the conductive metal in the part other than the inside of the groove pattern for lower layer wiring 106 and the lower layer large area groove pattern 107 is removed by conducting CMP (chemical mechanical polishing), to form a lower layer wiring pattern 108 in the device forming region and a light transmission inhibiting film 109 in the scribe region as shown in FIGS. 1 (C1) and (C2).

As a material of the lower layer wiring pattern 108 and the light transmission inhibiting film 109, conductive metal such as aluminum (Al), tungsten (W), tantalum (Ta), titanium (Ti) or the like may be used instead of copper.

In the step explained in FIG. 1(A1) to (C2), a lower layer wiring pattern for measurement (omitted in the drawing) may be formed for shape measurement of the lower layer wiring pattern 108 in a region different from that of the light transmission inhibiting film 109 in the scribe region and, further preferably, in a region different from that of the base scribe structure 102 (scribe region where the base scribe structure is absent). The timing and condition of forming this lower layer wiring pattern for measurement is as same as those of the lower layer wiring pattern 108.

Thereafter, the step (b) and the step (c) as described above are conducted concurrently.

The step (b) includes a step (b1) of forming an insulation film on the light transmission inhibiting film 109, a step (b2) of forming a resister pattern for forming a pattern for measurement on the insulation film by a photolithography method, a step (b3) of forming a groove pattern for measurement by etching the insulation film using the resist pattern as a mask, and a step (b4) of forming the pattern for measurement by embedding a conductive material inside the groove pattern for measurement.

Further, the step (c) includes a step (c1) of forming an insulation film on the semiconductor substrate 1, a step (c2) of forming a resist pattern for forming a wiring pattern on the insulation film by a photolithography method, a step (c3) of forming a groove pattern for wiring by etching the insulation film using the resist pattern as a mask, and a step (c4) of forming the wiring pattern by embedding a conductive material inside the groove pattern for wiring.

In the steps (b1) and (c1), on the entire surface of the semiconductor substrate 1 obtained through the steps as described above, a third insulation film 110 having a film thickness of 10 nm to 100 nm and a fourth insulation film 111 having a film thickness of 500 nm to 1000 nm are sequentially formed as shown in FIGS. 2(A1) and (A2). Here, the third insulation film 110 serves as an etching stopper layer when the later-described upper layer wiring pattern is formed in the fourth insulation film 111, and may be implemented by an inorganic insulation film made of, for example, SiC, SiCN or the like. The fourth insulation film 111 may be implemented by an inorganic insulation film made of, for example, silicon oxide, SiOF, SiOC, porous silica or the like.

Then, in the steps (b2) and (c2), first, on the fourth insulation film 111, a second resist pattern 112 having a film thickness of about 100 nm to 1000 nm is formed. The second resist pattern 112 is a resist pattern for formation of a via-hole, and has a mask opening part only in the device forming region. The second resist pattern 112 may be formed by a known method, and for example, may be formed by applying a photoresist composition, exposing it to light with an optimum light exposure amount and focus using a KrF excimer laser scanner, and conducting development. As the photoresist composition, for example, a chemical amplification positive-type photoresist composition containing a commonly used base resin, an acid generator and the like may be used.

Then dry etching using etching gas such as CₓF_{y}, CₓH_{y}F_{z}, O₂, CO, Ar or the like is conducted while the second resist pattern 112 is used as a mask, to form a via-hole 113 in the fourth insulation film 111 in the device forming region as shown in FIG. 2(B1). At this time, the third insulation film 110 serves as an etching stopper layer. On the other hand, in the scribe region, since the second resist pattern 112 has no opening part, a via-hole is not formed in the fourth insulation film 111 as shown in FIG. 2(B2).

Thereafter, plasma ashing is conducted using ashing gas containing oxygen gas to remove the second resist pattern 112.

Sequentially, as shown in FIGS. 2(C1) and (C2), an embedding film 114 is deposited on the fourth insulation film 111 in such a film thickness that completely embeds inside the via-hole 113. The embedding film 114 is a protective film of the third insulation film 110 in forming the upper layer wiring pattern in the fourth insulation film 111, and may be implemented, for example, by an organic film made of a resist material or the like, or an inorganic insulation film made of SOG or the like.

Thereafter, on the embedding film 114, a third resist pattern 115 having a film thickness of about 100 nm to 1000 nm is formed. The third resist pattern 115 is a resist pattern which is an object to be formed in the steps (b2) and (c2). At this time, as shown in FIG. 2(C1), in the device forming region in the third resist pattern 115, a mask opening part is formed according to a design layout of pattern shape having a wiring width, a film thickness and a wiring pitch (pattern interval) of an upper layer wiring pattern 118 (see FIG. 3 (B1)), and in a similar manner, in the scribe region in the third resist pattern 115, a mask opening part is formed according to the design layout of the upper layer wiring pattern 118. Accordingly, a part of the mask opening part of the third resist pattern 115 in the device forming region is positioned at the position of the via-hole 113.

The third resist pattern 115 may be formed by a known method, and for example, may be formed by applying a photoresist composition, exposing it to light with an optimum light exposure amount and focus using a KrF excimer laser scanner, and conducting development. As the photoresist composition, for example, a chemical amplification positive-type photoresist composition containing a commonly used base resin, an acid generator and the like may be used.

Thereafter, in the present invention, a forming part of the pattern for measurement in the third resist pattern 115 is exposed to measuring light, and the shape of the third resist pattern 115 is measured and evaluated by analyzing the reflected light, and when the evaluation is outside the reference value, the formation and measurement and evaluation of the third resist pattern 115 may be repeated until evaluation within the reference value is obtained by correcting the light exposure condition in the steps (b2) to (c2) after removing the third resist pattern 115.

In measurement, since the light transmission inhibiting film 109 is formed on the base scribe structure 102 in the scribe region, and there is no pattern between the light transmission inhibiting film 109 and the third resist pattern 115, the measuring light having transmitted through the third resist pattern 115 will be totally reflected by the light transmission inhibiting film 109 and detected by a measuring device without being influenced by another pattern than the third resist pattern 115. In other words, the parameters to be considered in this measurement are merely a depth, an upper side dimension, a lower side dimension, a side wall angle of the third resist pattern 115, a film thickness of the embedding film 114, a film thickness of the fourth insulation film 111 and a film thickness of the third insulation film 110, and such a small number of parameters to be considered simplifies fitting between an actually measured waveform and a theoretical waveform, so that optimum solutions can be obtained with high accuracy.

In this measurement, for example, measurement by a scatterometry method is preferred.

When evaluation in this step is outside the reference value, the third resist pattern 115 is determined as having a defective shape, and hence removed, and thereafter, the formation and measurement and evaluation of the third resist pattern 115 are repeated until evaluation within the reference value is obtained by correcting the light exposure condition in the steps (b2) to (c2), and when the evaluation falls within the reference value, it is determined that the third resist pattern 115 has a shape within an allowable range, and the flow proceeds to the next steps (b3) and (c3).

In the steps (b3) and (c3), the embedding film 114 and the fourth insulation film 111 are dry-etched by using etching gas such as CₓF_{y}, CₓH_{y}F_{z}, O₂, CO, Ar or the like while using the third resist pattern 115 as a mask, to form a groove pattern for upper layer wiring 116 and a groove pattern for measurement 117. As shown in FIGS. 3 (B1) and (B2), this dry etching is controlled so that, in the device forming region and in the scribe region, the groove pattern for upper layer wiring 116 and the groove pattern for measurement 117 are formed in a depth that is as same as the film thickness of the upper layer wiring pattern 118, for example, 200 nm to 800 nm in the fourth insulation film 111. In this dry etching, in the device forming region, the embedding film 114 within the via-hole 113 functions as a protective film of the third insulation film 110, and the embedding film 114 remains in the via-hole 113.

Thereafter, plasma ashing is conducted using ashing gas containing oxygen gas, to remove the third resist pattern 115 and the embedding insulation film 114 remaining in the via-hole 113. Sequentially, dry etching is conducted using etching gas such as CₓF_{y}, CₓH_{y}F_{z}, O₂, CO, Ar or the like, to remove the third insulation film 110, whereby, as shown in FIGS. 3(A1) and (A2), the via-hole 113 and a part of the groove pattern for upper layer wiring 116 are exposed in the device forming region while they communicate to the lower layer wiring pattern 108.

Next, in the steps (b4) and (c4), a conductive metal film is deposited on the fourth insulation film 111 in such a thickness that is completely embedded into the via-hole 113 and the groove pattern for upper layer wiring 116, and the metal film on the surface is removed by conducting CMP (chemical mechanical polishing), to make the fourth insulation film 111 exposed. As a result, in the device forming region, a via pattern 120 and the upper layer wiring pattern 118 are formed as shown in FIG. 3(B1), and at the same time, in the scribe region, as shown in FIG. 3(B2), an upper layer wiring pattern for measurement 119 is formed.

Since the upper layer wiring pattern 118 formed in this manner is based on the third resist pattern 115 having passed the evaluation of shape measurement, it is formed to have shape that does not depart from the design layout. The shape measurement and evaluation of the upper layer wiring pattern for measurement 119 are not conducted in the present first embodiment, however, they may be conducted as is the embodiment described later.

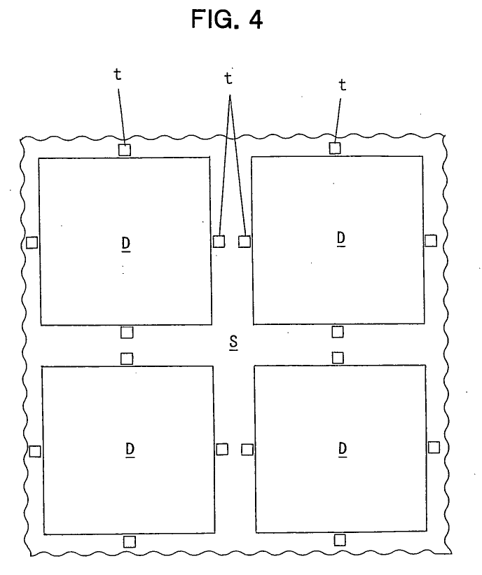

FIG. 4 is a arrangement view showing a device forming region and a region of upper layer wiring pattern for measurement in the first embodiment.

In the wiring structure of the first embodiment formed as described above, a region t where the upper layer wiring pattern for measurement 119 is formed (hereinafter, referred to as “test region t”) is a scribe region S and arranged one for one side of peripheral four sides of a device forming region D so that a large area is ensured for the device forming region D as shown in FIG. 4.

More specifically, the test region t is arranged in a middle position in the longitudinal direction of each side of the device forming region D, and this arrangement is uniform in every device forming region D. As a result, whether difference occurs between the center part and the peripheral part of the substrate in the pattern shape can be observed.

A size of the device forming region D is about 1000 μm to 20000 μm square, a width of the scribe region S is about 50 μm to 200 μm, and a size of the test region t is about 30 μm to 70 μm square.

The sizes of the four test regions t arranged along one device forming region D may be the same or different, and may be the same or different upper layer wiring pattern for measurement 119. In the case of different upper layer wiring patterns for measurement 119, shape measurement may be conducted while assigning arbitrary plural parts in the upper layer wiring pattern 118 of the device forming region D to each upper layer wiring pattern for measurement 118 of the four test regions t.

On the other hand, it is suffices that the light transmission inhibiting film 109 has an arrangement, a shape and a size that is overlapped in substantially coincidence with at least the test region t, and only one light transmission inhibiting film 109 may be overlapped with two adjacent test regions t.

### Second Embodiment

In the second embodiment, in addition to the shape measurement and evaluation of the third resist pattern 115 conducted in the first embodiment, shape measurement and evaluation of the groove pattern for measurement 117 formed in the fourth insulation film 111 are conducted. In this case, as the optical shape measuring method, a scatterometry method is preferred.

By conducting the shape measurement of the groove pattern for measurement 117 in this manner, it is possible to feed back the measurement result to a new production cycle, and hence it is possible to control the shape of the upper layer wiring pattern 118 with higher accuracy.

### Third Embodiment

In the third embodiment, in addition to the shape measurement and evaluation of the third resist pattern 115 conducted in the first embodiment, the shape measurement and evaluation of the pattern for measurement 119 are conducted. Also in this case, a scatterometry method is preferred as optical shape measuring method.

Also by conducting the shape measurement of the pattern for measurement 119 in this manner, it is possible to feed back the measurement result to a new production cycle, and hence it is possible to control the shape of the upper layer wiring pattern 118 with higher accuracy. The shape measurement and evaluation of the groove pattern for measurement 117 may further combined.

### Fourth Embodiment

In the first embodiment, explanation was made for the case where the light transmission inhibiting film 109 explained in FIG. 1(C2) is formed concurrently with the lower layer wiring pattern 108 using the same conductive metal material, however, in the fourth embodiment, the material of the light transmission inhibiting film 109 is formed of a metal compound such as tungsten nitride (WN), tantalum nitride (TaN) or titanium nitride (TiN) or an insulating material such as silicon nitride (SiN) or silicon nitride oxide (SiON). In this case, the light transmission inhibiting film 109 and the lower layer wiring pattern 108 are formed in different steps.

Concretely, in the manner as explained in FIGS. 1(A1), (B1) and (C1), the lower layer wiring pattern 108 is first formed inside the fourth insulation film 104 and the third insulation film 103 in the device forming region. Since the first resist pattern 105 that is formed at first in the step shown in FIG. 1(A1) does not have an opening part in the scribe region, the second insulation film 104 and the third insulation film 103 still remain without being etched.

Thereafter, in the manner as described in FIGS. 1(A2), (B2) and (C2), the fourth insulation film 104 and the third insulation film 103 in the scribe region are etched, and an insulating material is embedded, to form the light transmission inhibiting film 109. Since the first resist pattern 105 formed secondly in the step shown in FIG. 1(A2) does not have an opening part in the device forming region, the lower layer wiring pattern 108 is protected.

By forming the light transmission inhibiting film 109 of a metal compound such as WN, TaN or TiN or an insulating material such as SiN or SiON, an effect of preventing diffusion of wiring metal material such as Cu is expected, and the light transmission inhibiting film 109 that is formed of such a metal compound or insulating material also serves as a base film in deposition of the wiring metal. These metal compound or insulating material may be used as a cap film of metal wiring (third insulation film 110).

### Fifth Embodiment

In the first embodiment, explanation was made for a two-layer wiring structure having the lower layer wiring pattern 108 of the first layer and the upper layer wiring pattern 118 of the second layer, however, the present invention may be applied to a wiring structure having three or more layers.

As for a three-layer wiring structure, for example, in the device forming region, after forming the wiring pattern of the first layer and the wiring pattern of the second layer through the similar steps as in the first embodiment, a fifth insulation film and a sixth insulation film are formed, and on the sixth insulation film, a fourth resist pattern for forming a third wiring pattern is formed.

On the other hand, in the scribe region, in the step of FIG. 2(C2), a third resist pattern having an opening part in a region directly above the light transmission inhibiting film 109 and an opening in a region other than this region (hereinafter, referred to as “other region”) is formed. In this third resist pattern, in the region directly above the light transmission inhibiting film 109, a pattern opening part for measurement of the shape of the upper layer wiring pattern is formed likewise the first embodiment, while in the other region, a large area pattern opening part is formed.

Next, the fourth insulation film 111 is dry-etched by using the third resist pattern as a mask, and as a result, the upper layer wiring groove pattern for measurement 117 is formed in the region directly above the light transmission inhibiting film 109 likewise the first embodiment, and a large area groove pattern is formed in the other region as shown in FIG. 3(A2).

Sequentially, by embedding a conductive metal material in the upper layer wiring pattern for measurement 117 and the large area groove pattern, the upper layer wiring pattern for measurement 119 and a second light transmission inhibiting film are formed. Thereafter, the fifth insulation film and the sixth insulation film are formed, and the fourth resist pattern is formed on the sixth insulation film. In this fourth resist pattern, directly above the second light transmission inhibiting film, a pattern opening part having the same shape as the wiring pattern of the third layer is formed.

Thereafter, the shape of the pattern of the scribe region in the fourth resist pattern is measured and evaluated in the same manner as the first embodiment by an optical shape measuring method. At this time, since the second light transmission inhibiting film is present directly below the pattern, even when, for example, a lower layer wiring pattern for measurement having the same shape as the lower layer wiring pattern or the base scribe structure 102 is present directly below the second light transmission inhibiting film, the shape measurement can be conducted without being influenced by these pattern and base scribe structure.

When the result of the shape measurement is outside the reference value, the fourth resist pattern is removed, and the fourth resist pattern is formed repeatedly until acceptance is obtained while correcting the light exposure condition. When acceptance is obtained, the sixth insulation film is dry-etched by using the fourth resist pattern as a mask, to form a wiring groove pattern and a wiring groove pattern for measurement in the device forming region and in the scribe region, and then a conductive metal material is embedded in the wiring groove pattern and the wiring groove pattern for measurement, to form a wiring pattern and a wiring pattern for measurement of the third layer.

It is preferred to control a shape by conducting the optical shape measurement on at least one of the wiring groove pattern for measurement and the wiring pattern for measurement.

Furthermore, in the case of a four-layer wiring structure, in forming the fourth resist pattern described above, a large area pattern opening part is also formed in the region other than the region directly above the second light transmission inhibiting film in the scribe region, and the sixth insulation film is dry-etched by using the fourth resist pattern as a mask, to form the wiring groove pattern and the large area groove pattern.

Then, a conductive metal material is embedded in the wiring groove pattern and the large area groove pattern, to form the wiring pattern for measurement and the third light transmission inhibiting film of the third layer. During this formation, in the device forming region, a wiring pattern of the third layer is formed in a similar manner as described above.

Thereafter, in the device forming region and the scribe region, a seventh insulation film and an eighth insulation film are formed, and a fifth resist pattern is formed on the eighth insulation film. The fifth resist pattern has a pattern opening part for forming a wiring pattern of the fourth layer in the device forming region, and has a pattern opening part for shape measurement of the wiring pattern of the fourth layer directly above the third light transmission inhibiting film in the scribe region.

Then optical shape measurement is conducted on this pattern for shape measurement in the fifth resist pattern. When the measurement result is accepted, the eighth insulation film is dry-etched to form a groove pattern and the groove pattern for measurement in the device forming region and the scribe region, and a conductive metal material is embedded in the groove pattern and the groove pattern for measurement, to form a wiring pattern and a wiring pattern for measurement of the fourth layer.

It is preferred to control a shape by conducting the optical shape measurement on at least one of the groove pattern for measurement and the wiring pattern for measurement.

In the case of a four-layer wiring structure, as another production method, after forming a two-layer wiring structure as shown in FIGS. 3 (b1) and (b2) likewise the first embodiment, the second lower layer wiring pattern and the second light transmission inhibiting film are formed as the third layer in the device forming region and the scribe region in accordance with the production process of the two-layer wiring structure, and the second upper layer wiring pattern and the second upper layer wiring pattern for measurement are formed as the fourth layer.

In this case, the optical shape measurement is conducted on the resist pattern for forming the second upper layer wiring pattern, and it is preferred to control a shape by conducting the optical shape measurement on at least one of the second upper layer wiring groove pattern for measurement and the second upper layer wiring pattern for measurement.

### Other Embodiment

In the first embodiment, the case where the light transmission inhibiting film 109 and the pattern for measurement 119 are formed in the scribe region S is exemplified, however, they may be formed in the device forming region D.

Further, the test region t may be arranged in two or more positions per side of the square device region D.

What is claimed is:

1. A wiring structure comprising a wiring pattern formed in an insulation film on a substrate, a pattern for measurement which is formed in the insulation film on the substrate in a region different from a region where the wiring pattern is formed and is irradiated with measuring light, and a light transmission inhibiting film formed directly below the pattern for measurement, wherein
the pattern for measurement is the same pattern as the wiring pattern, and
the light transmission inhibiting film is made of a material having light transmissivity that is smaller than light transmissivity of a material of the insulation film forming the pattern for measurement.

2. The wiring structure according to claim 1, further comprising a lower layer pattern structure containing at least one of a wiring and an element, directly below the light transmission inhibiting film.

3. The wiring structure according to claim 1, wherein the substrate includes a plurality of device forming regions and a scribe region that partitions the plurality of device forming regions, the wiring pattern is formed in the device forming region, and the pattern for measurement is formed in the scribe region.

4. The wiring structure according to claim 1, wherein the device forming region is quadrangular, and the pattern for measurement is arranged along each side in peripheral four sides of the device forming region.

5. The wiring structure according to claim 2, wherein the device forming region has a base device structure formed on a surface of the substrate, a first insulation film formed on the base device structure, a second insulation film formed on the first insulation film, a lower layer wiring pattern formed inside the first insulation film and the second insulation film, a third insulation film formed on the lower layer wiring pattern, a fourth insulation film formed on the third insulation film, and the wiring pattern formed inside the third insulation film and the fourth insulation film, and
the scribe region has the lower layer pattern structure formed on the surface of the substrate, for measuring dimension of the base device structure, the first insulation film and the second insulation film formed on the lower layer pattern structure, the light transmission inhibiting film formed inside the first insulation film and the second insulation film, the third insulation film and the fourth insulation film formed on the light transmission inhibiting film, and the pattern for measurement formed inside the third insulation film and the fourth insulation film.

6. The wiring structure according to claim 1, wherein the measuring light has a wavelength ranging from 200 nm to 800 nm.

7. The wiring structure according to claim 1, wherein a material of the insulation film forming the pattern for measurement is silicon oxide, SiOF, SiOC, SiC, SiCN, SiOCH or porous silica, and a material of the light transmission inhibiting film is Cu, Al, W, WN, Ta, TaN, Ti, TiN, SiN or SiON.

8. The wiring structure according to claim 1, wherein the light transmissivity of the light transmission inhibiting film is 0 to 0.95 time the light transmissivity of the insulation film forming the pattern for measurement.

9. The wiring structure according to claim 6, wherein the light transmission inhibiting film has a two-dimensional size that is equal to or larger than a beam diameter of the measuring light, and the pattern for measurement has a two-dimensional size that is equal to or larger than a beam diameter of the measuring light, and has a wiring width and a wiring pitch of one-tenth to 10 times of a wavelength of the measuring light.

10. The wiring structure according to claim 9, wherein the two-dimensional size of the pattern for measurement is 10 μm square or more and 100 μm square or less.

11. The wiring structure according to claim 6, wherein the pattern for measurement is a repeated pattern having a single wiring width and a single wiring pitch.

12. A method of producing the wiring structure of claim 1, comprising the steps of:
(a) forming the light transmission inhibiting film on the substrate,
(b) forming an insulation film directly above the light transmission inhibiting film, and forming the pattern for measurement in the insulation film, and
(c) forming an insulation film on the substrate in a region which is different from that of the light transmission inhibiting film, and forming the wiring pattern in the insulation film,
wherein the step (b) and the step (c) are conducted concurrently.

13. The method of producing the wiring structure according to claim 12, wherein the step (b) includes the steps of: (b1) forming the insulation film on the light transmission inhibiting film; (b2) forming a resist pattern for forming a pattern for measurement on the insulation film by a photolithography method; (b3) forming a groove pattern for measurement by etching the insulation film using the resist pattern as a mask; and (b4) forming the pattern for measurement by embedding a conductive material inside the groove pattern for measurement.

14. The method of producing the wiring structure according to claim 13, wherein between the step (b2) and the step (b3), a shape of the resist pattern is measured and evaluated by irradiating the resist pattern with measuring light and analyzing its reflected light, and when the evaluation is outside a reference value, formation and measurement and evaluation of the resist pattern is repeated while light exposure condition in the step (b2) is corrected after removing the resist pattern, until evaluation within the reference value is obtained.

15. The method of producing the wiring structure according to claim 13, further comprising, between the step (b3) and the step (b4), the step of measuring and evaluating a shape of the groove pattern for measurement by irradiating the groove pattern for measurement with measuring light and analyzing its reflected light.

16. The method of producing the wiring structure according to claim 12, further comprising, after the step (b), a step (d) of measuring and evaluating a shape of the pattern for measurement by irradiating the formed pattern for measurement with measuring light, and analyzing its reflected light.
